(19) United States
(12) Patent Application Publication
(10) Pub. No.: US 2022/0189858 A1
(43) Pub. Date: Jun. 16, 2022

(54) SEMICONDUCTOR DEVICE PACKAGES INCLUDING MULTIPLE LEAD FRAMES AND RELATED METHODS

(71) Applicant: Microchip Technology Incorporated, Chandler, AZ (US)

(72) Inventor: J. Andrew Kovats, Manitou Springs, CO (US)

(21) Appl. No.: 17/301,864

(22) Filed: Apr. 16, 2021

Related U.S. Application Data
(60) Provisional application No. 63/124,198, filed on Dec. 11, 2020.

(51) Int. Cl. H01L 23/495; H01L 21/48; H01L 23/31; H01L 21/56; H01L 23/00; H01L 21/78

(52) U.S. Cl. CPC H01L 23/49537; H01L 23/49548; H01L 21/4821; H01L 23/3107; H01L 2224/16245; H01L 21/563; H01L 24/16; H01L 21/78; H01L 21/565

(57) ABSTRACT

Semiconductor device packages may include a semiconductor die including a first major surface affixed and electrically connected to a first lead frame. A second lead frame may be affixed and electrically connected to a second major surface located on a side of the semiconductor die opposite the first major surface. A molding material may encapsulate the semiconductor die and at least portions of the first lead frame and the second lead frame.

### CROSS-REFERENCE TO RELATED APPLICATION

This application claims the benefit under 35 U.S.C. § 119(e) of U.S. Provisional Patent Application Ser. No. 63/124,198, filed Dec. 11, 2020, for, “Semiconductor Device Packages Including Multiple Lead Frames and Related Methods,” the disclosure of which is incorporated herein in its entirety by this reference.

### FIELD

This disclosure relates generally to semiconductor device packages including lead frames and methods of fabricating semiconductor device packages including lead frames. More specifically, disclosed embodiments relate to semiconductor device packages that may utilize multiple lead frames having one or more semiconductor devices interposed between the lead frames.

### BACKGROUND

A lead frame is one conventional approach to package semiconductor devices for use with higher-level packaging. Typically, lead frames include a die-attach pad on which a semiconductor die may be supported and lead fingers extending from proximate to the die-attach pad at an angle. Pads on a side of the semiconductor die opposite the die-attach pad may be electrically connected to the lead fingers by wire bonds. The semiconductor die, die-attach pad, wire bonds, and portions of the lead fingers may be encapsulated in a molding material. Remainders of the lead fingers may be exposed on one side of the semiconductor die for mechanically and electrically connecting the resulting semiconductor device package to higher-level packaging, such as a printed circuit board.

Another conventional approach is to package a semiconductor device with a copper clip. Typically, copper clips include a die-attach tab on which a semiconductor die may be supported and an overlying clip for connecting to the pads of the semiconductor die on a side opposite the die-attach tab. Lead fingers may extend from the clip at an angle from the side where the clip is located, past the semiconductor die, proximate to the die-attach tab. The semiconductor die, die-attach tab, overlying clip, and portions of the lead fingers may be encapsulated in a molding material. Remainders of the lead fingers may be exposed on one side of the semiconductor die for mechanically and electrically connecting the resulting semiconductor device package to higher-level packaging.

### BRIEF SUMMARY

In some embodiments, semiconductor device packages may include a semiconductor die having a first major surface affixed and electrically connected to a first lead frame. A second lead frame may be affixed and electrically connected to a second major surface located on a side of the semiconductor die opposite the first major surface. A molding material may encapsulate the semiconductor die and at least portions of the first lead frame and the second lead frame.

In other embodiments, semiconductor device packages may include a first semiconductor die having a first major surface affixed and electrically connected to a first lead frame. A second semiconductor die may have a second major surface affixed and electrically connected to a second lead frame, the second semiconductor die having a third major surface affixed to a fourth major surface of the first semiconductor die. The first lead frame may be located on a side of the first semiconductor die opposite the second semiconductor die and the second lead frame may be located on a side of the second semiconductor die opposite the first semiconductor die. A molding material may encapsulate the first semiconductor die, the second semiconductor die, and at least portions of the first lead frame and the second lead frame.

In other embodiments, methods of concurrently making semiconductor device packages may involve affixing a first major surface of each of a plurality of semiconductor dice, and electrically connecting each semiconductor die, to respective first die-attach locations of a first lead frame. A second major surface of each semiconductor die may be affixed, and each semiconductor die may be electrically connected, to respective second die-attach locations of a second lead frame, the second lead frame located on a side of each semiconductor die opposite the first lead frame. The semiconductor dice and at least portions of the first lead frame and the second lead frame may be encapsulated in a molding material.

In still other embodiments, methods of concurrently making semiconductor device packages may involve affixing a first major surface of each of a plurality of first semiconductor dice, and electrically connecting each first semiconductor die, to respective first die-attach locations of a first lead frame. A second major surface of each of a plurality of second semiconductor dice may be affixed, and each second semiconductor die may be electrically connected, to respective second die-attach locations of a second lead frame. Each first semiconductor die may be secured to a corresponding second semiconductor die, the first lead frame located on a side of each first semiconductor die opposite the corresponding second semiconductor die, the second lead frame located on a side of each second semiconductor die opposite the first semiconductor die. The first semiconductor dice, the second semiconductor dice, and at least portions of the first lead frame and the second lead frame may be encapsulated in a molding material.

### BRIEF DESCRIPTION OF THE DRAWINGS

While this disclosure concludes with claims particularly pointing out and distinctly claiming specific embodiments, various features and advantages of embodiments within the scope of this disclosure may be more readily ascertained from the following description when read in conjunction with the accompanying drawings. In the drawings:

FIG. 1 is a cross-sectional, side, schematic view of a semiconductor device package in accordance with this disclosure; and

FIG. 2 is a perspective side view of the semiconductor device package of FIG. 1, with certain features removed to more clearly illustrate other features;

FIG. 3 is a cross-sectional, side, schematic view of another embodiment of a semiconductor device package in accordance with this disclosure;

FIG. 4 is a top schematic view of a first intermediate product in a first stage of a method of concurrently making multiple semiconductor device packages;

FIG. 5 is a top schematic view of an intermediate product in a second stage of a method of concurrently making multiple semiconductor device packages;

FIG. 6 is a flowchart of a method of concurrently making multiple semiconductor device packages; and

FIG. 7 is a flowchart of another embodiment of a method of concurrently making multiple semiconductor device packages.

### DETAILED DESCRIPTION

The illustrations presented in this disclosure are not meant to be actual views of any particular semiconductor device package, intermediate product in a method of making a semiconductor device package, or component thereof, but are merely idealized representations employed to describe illustrative embodiments. Thus, the drawings are not necessarily to scale.

Disclosed embodiments relate generally to semiconductor device packages that may utilize multiple lead frames having one or more semiconductor devices interposed between the lead frames. More specifically, disclosed are embodiments of semiconductor device packages that may enable electrical connection on opposite sides of the semiconductor device packages, may accommodate multiple semiconductor dice within a given semiconductor device package, may enable collective, concurrent packaging of multiple semiconductor device packages, may provide exposed structures for electrical and thermal management connections, and may be implementable with little added cost to existing packaging processes.

For example, semiconductor device packages may include a first lead frame located proximate to a first major surface of a semiconductor die and a second lead frame located proximate to a second major surface, and on an opposite side of, the semiconductor die. Each of the first lead frame and the second lead frame may be electrically connected to one or more semiconductor dice within the semiconductor device package. The first lead frame may also be electrically connected to the second lead frame. In some embodiments, the semiconductor device package may include a single semiconductor die, and the first and second lead frames may be affixed, and electrically connected, to respective major surfaces (e.g., an active surface including integrated circuitry, an inactive surface free of integrated circuitry) of the semiconductor die. In other embodiments, multiple semiconductor dice may be provided in a single semiconductor device package (e.g., in a stack), with the first lead frame affixed, and electrically connected, to a first semiconductor die and the second lead frame affixed, and electrically connected, to a second semiconductor die. In some embodiments, one or more passive devices (e.g., capacitors, resistors) may be contained within the package, may be directly electrically connected to the first lead frame or the second lead frame, and may be stacked with a semiconductor die or located laterally adjacent to the semiconductor die.

Each semiconductor die, any passive devices, and at least portions of each of the first lead frame and the second lead frame may be encapsulated in a molding material. At least one of the first lead frame and the second lead may include exposed portions of electrically conductive material (e.g., bond pads, lead fingers, traces) for forming electrical connections with higher-level packaging (e.g., a printed circuit board, another semiconductor device package). In some embodiments, both of the first lead frame and the second lead frame may include exposed portions of electrically conductive material for forming electrical connections with higher-level packaging. In other embodiments, one of the first lead frame or the second lead frame may include such exposed portions, and the other of the first lead frame or the second lead frame may be completely concealed within the molding material. In some embodiments, one or both of the first and second lead frames may include another exposed portion of thermally conductive material for forming a thermal connection with a thermal management structure (e.g., a heat sink, a heat spreader).

When forming semiconductor device packages in accordance with this disclosure, the first and second lead frames may be provided in first and second strips. Any semiconductor dice, passives, and bridging elements for connecting the first and second lead frames may be provided on the first lead frame, the second lead frame, or respective components may be provided separately on the first lead frame or the second lead frame, with at least one component on each lead frame. The first lead frame may be brought proximate to the second lead frame, and the molding material may flow around each semiconductor device, any passive devices, and at least portions of the first and second lead frames. The molding material may be placed in a cured state, and individual semiconductor device packages may be singulated from one another and from any waste material of the first and second strips.

As used herein, the terms “substantially” and “about” in reference to a given parameter, property, or condition means and includes to a degree that one of ordinary skill in the art would understand that the given parameter, property, or condition is met with a degree of variance, such as within acceptable manufacturing tolerances. For example, a parameter that is substantially or about a specified value may be at least about 90% the specified value, at least about 95% the specified value, at least about 99% the specified value, or even at least about 99.9% the specified value.

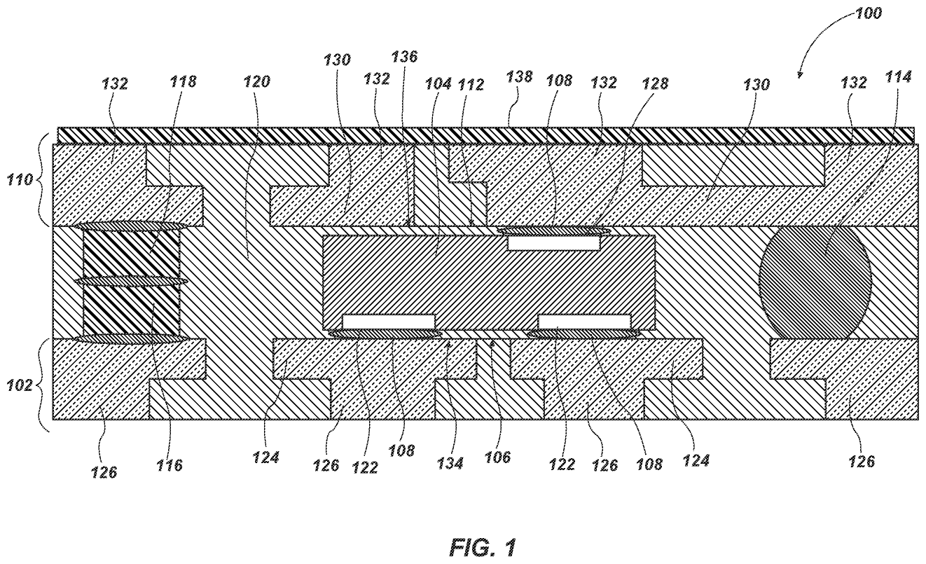

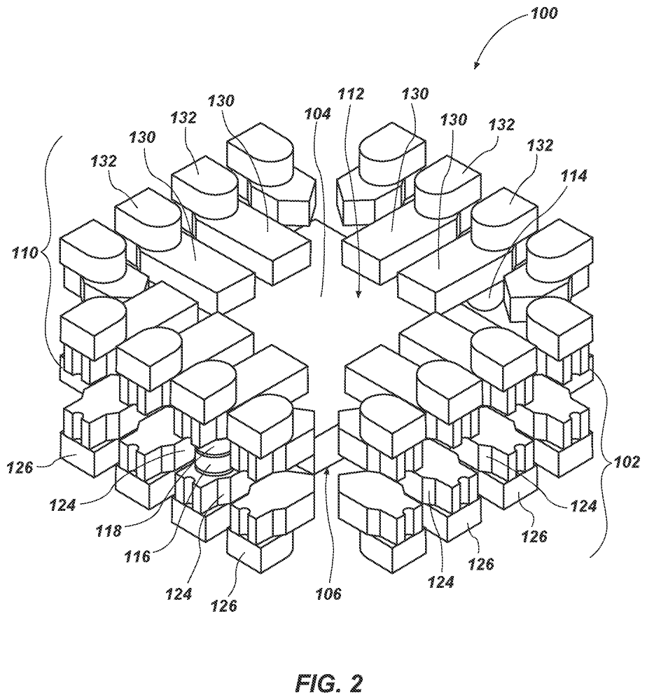

FIG. 1 is a cross-sectional, side, schematic view of a semiconductor device package 100 in accordance with this disclosure. FIG. 2 is a perspective side view of the semiconductor device package 100 of FIG. 1, with certain features removed to more clearly illustrate other features. Specifically, a molding material 120 of the semiconductor device package 100 of FIG. 1 has been removed from the semiconductor device package 100 of FIG. 2 to more clearly illustrate the structure of a first lead frame 102 and a second lead frame 110 of the semiconductor device package 100. With combined reference to FIG. 1 and FIG. 2, the semiconductor device package 100 may include, for example, first lead frame 102 positioned proximate to a first major surface 106 of a semiconductor die 104.

In some embodiments, the first major surface 106 may be an active surface, having integrated circuitry embedded within and/or supported on the first major surface 106. In some such embodiments, the first major surface 106 may be affixed, and electrically connected, to the first lead frame 102 with the semiconductor die 104 placed in a first die-attach location 134 on the first lead frame 102. For example, the semiconductor die 104 may be in a flip-chip orientation relative to the first lead frame 102, and first bond pads 122 of the semiconductor die 104 exposed at the first major surface 106 may be electrically connected to the first lead frame 102 by electrically conductive elements 108 interposed between the first bond pads 122 and the first lead frame 102. The conductive elements 108 may be configured as, for example, balls, bumps, columns, pillars, or other shapes of, or including, electrically conductive material (e.g., solder, electrically conductive paste). The conductive elements 108 may affix, and electrically connect, the semiconductor die 104 to a die-attach pad, individual first lead fingers 124, or one or more first bond pads 122 to the die-attach pad and other first bond pads 122 to respective first lead fingers 124 for routing signals from integrated circuitry of the active surface to first output lands 126 of the first lead frame 102 and to higher-level packaging. Such first output lands 126 may include portions of the first lead frame 102 exposed through the molding material 120 for electrically connecting to higher level packaging (e.g., utilizing solder to mount the semiconductor device package 100 to a printed circuit board). In some embodiments, the higher-level packaging may include another semiconductor device package affixed, and electrically connected to, the semiconductor device package 100 utilizing the first output lands 126 of the first lead frame 102.

The first lead frame 102 may include, for example, electrically conductive material (e.g., copper, gold, aluminum, alloys) positioned and configured to carry and route electrical signals and/or power to and from the semiconductor die 104. The first lead frame 102 may be at least substantially planar. For example, the first lead frame 102 may lack bends or lead fingers extending at oblique angles relative to the first major surface 106. More specifically, the first lead frame 102 may primarily be composed of one or more layers or sheets of electrically conductive material including first lead fingers 124 positioned and configured to form electrical connections with first bond pads 122 on the first major surface 106 of the semiconductor die 104 and to route electrical signals and/or power to and from the semiconductor die 104, and first output lands 126 positioned and configured to present locations for connection to higher-level packaging (e.g., a printed circuit board (PCB)). As a specific, nonlimiting example, the first lead frame 102 may be formed from a dual-depth etched sheet of electrically conductive material, and may include first lead fingers 124 extending laterally proximate to the first major surface 106 of the semiconductor die 104, some of which may be affixed, and electrically connected, to first bond pads 122 at the first major surface 106, and first output lands 126 located laterally outward from the first bond pads 122 and on a side of the first lead fingers 124 opposite a side on which the first major surface 106 of the semiconductor die 104 is located. In some embodiments, the first lead frame 102 may lack any die-attach pad.

A maximum thickness of the first lead frame 102, as measured in the direction at least substantially perpendicular to the first major surface 106, may be less than the thickness of a conventional lead frame having lead fingers extending at oblique angles relative to the first major surface 106. For example, the maximum thickness of the first lead frame 102 may be about 225 microns or less. More specifically, the maximum thickness of the first lead frame 102 may be between about 75 microns and about 200 microns. As a specific, nonlimiting example, the maximum thickness of the first lead frame 102 may be between about 100 microns and about 200 microns (e.g., about 125 microns, about 150 microns, about 175 microns).

The semiconductor die 104 may include integrated circuitry to enable the resulting semiconductor device package 100 to perform a predetermined function. For example, the semiconductor die 104 may include field-effect transistors, and may be configured as, for example, a microprocessor or system-on-a-chip. While semiconductor device package 100 of FIG. 1 is depicted as including a single semiconductor die 104, semiconductor device packages in accordance with this disclosure may include multiple semiconductor dice interposed between the first lead frame 102 and the second lead frame 110 in other embodiments. For example, such semiconductor dice may be stacked back-to-back, with active surfaces facing a respective one of the first lead frame 102 or the second lead frame 110, or may be stacked with active surfaces facing a same direction, with one semiconductor die mounted to the first lead frame 102 in a flip-chip connection and the other semiconductor die connected to the second lead frame 110 by wire bonds or utilizing surface mount technology.

The semiconductor device package 100 may further include a second lead frame 110 positioned proximate to a second major surface 112 of the semiconductor die 104 with the semiconductor die 104 placed in a second die-attach location 136 on the second lead frame 110. The second major surface 112 may be on a side of the semiconductor die 104 opposite the first major surface 106. The second major surface 112 may be configured as, for example, an inactive surface lacking integrated circuitry. In some embodiments, the second major surface 112 may be affixed, and electrically connected, to the second lead frame 110. For example, the second major surface 112 may be electrically connected to the second lead frame 110 by electrically conductive elements 108 interposed between the second major surface 112 and a die-attach pad of the second lead frame 110, which may form, for example, a ground plane and/or an exposed surface for thermally connecting to a thermal management device. More specifically, the second major surface 112 may be electrically connected to the second lead frame 110 by a back-side metallization process (e.g., sputtering) or a surface mount (e.g., directly contacting the second lead frame 110 to the second major surface 112 with an electrically conductive material, such as, for example, solder, conductive paste, etc., therebetween). As another example, second bond pads 128 may be exposed at the second major surface 112, and the second bond pads 128 may be operatively and electrically connected to integrated circuitry at the first major surface 106 (e.g., utilizing through-silicon vias (TSVs)), and at least one of second lead fingers 130 of second lead frame 110 may be attached, and electrically connected, to a corresponding one of the second bond pads 128.

The second lead frame 110 may be distinct from the first lead frame 102. For example, the first lead frame 102 and the second lead frame 110 may not share lead fingers or die-attach pads, with first lead frame 102 including its own respective first lead fingers 124 and optional first die-attach pad, and with the second lead frame 110 including its own second lead fingers 130 and optional second die-attach pad. More specifically, the first lead frame 102 may be confined to a first side of the semiconductor die 104, and the second lead frame 110 may be confined to a second, opposite side of the semiconductor die 104, such that the structures of the first lead frame 102 and the second lead frame 110 may not cross a plane at least substantially bisecting the semiconductor die 104 and located at an average midpoint between the first major surface 106 and the second major surface 112. As a specific, nonlimiting example, the first lead fingers 124 (and any first die-attach pad) of the first lead frame 102 may be directly electrically connected only to first bond pads 122 on the first side of the semiconductor die 104 (e.g., utilizing respective conductive elements 108), and the second lead fingers 130 (and any second die-attach pad) of the second lead frame 110 may be directly electrically connected only to second bond pads 128 on the second side of the semiconductor die 104 (e.g., utilizing respective conductive elements 108).

In some embodiments, the first lead frame 102 may be physically spaced, and electrically unconnected, from the second lead frame 110. In other embodiments, the first lead frame 102 may be physically spaced from, but electrically connected to, the second lead frame 110. For example, bridging elements 114 may extend between the first lead frame 102 and the second lead frame 110 in locations outside a footprint of the semiconductor die 104, or vias extending through the semiconductor die 104 between the first major surface 106 and the second major surface 112, may electrically connect at least a portion of the first lead frame 102 to a corresponding portion of the second lead frame 110.

The second lead frame 110 may include, for example, electrically conductive material (e.g., copper, gold, aluminum, alloys) positioned and configured to carry and route electrical signals and/or power to and from the semiconductor die 104 and/or to provide electrical ground for the semiconductor die 104. The second lead frame 110 may be at least substantially planar. For example, the second lead frame 110 may lack bends or lead fingers extending at oblique angles relative to the second major surface 112. More specifically, the second lead frame 110 may primarily be composed of one or more layers or sheets of electrically conductive material including second lead fingers 130 positioned and configured to form electrical connections with the second major surface 112 itself and/or with second bond pads 128 on the second major surface 112 of the semiconductor die 104 and to route electrical signals and/or power to and from the semiconductor die 104, and second output lands 132 positioned and configured to present locations for connection to higher-level packaging (e.g., a printed circuit board (PCB)). As a specific, nonlimiting example, the second lead frame 110 may be formed from a dual-depth etched sheet of electrically conductive material, and may include second lead fingers 130 extending laterally proximate to the second major surface 112 of the semiconductor die 104, some of which may be affixed, and electrically connected, to second bond pads 128 at the second major surface 112, and second output lands 132 located laterally outward from any second bond pads 128 and on a side of the second lead fingers 130 opposite, i.e. distal of, the side the second major surface 112 of the semiconductor die 104 is located. Such second output lands 132 may include portions of the second lead frame 110 exposed through the molding material 120 for electrically connecting to higher level packaging (e.g., utilizing solder to mount the semiconductor device package 100 to a printed circuit board). In some embodiments, the second lead frame 110 may lack any die-attach pad. In some embodiments, the higher-level packaging may include another semiconductor device package affixed, and electrically connected to, the semiconductor device package 100 utilizing the second output lands 132 of the second lead frame 110. In some embodiments, the first lead frame 102, the second lead frame 110, or both may be temporarily supported on a respective tape 138 (e.g., a strip of polymer material including an adhesive material for temporarily affixing the respective first lead frame 102 or second lead frame 110 to the tape 138),

A maximum thickness of the second lead frame 110, as measured in the direction at least substantially perpendicular to the second major surface 112, may be less than the thickness of a conventional lead frame having lead fingers extending at oblique angles relative to the second major surface 112. For example, the maximum thickness of the second lead frame 110 may be about 250 microns or less. More specifically, the maximum thickness of the second lead frame 110 may be between about 10 microns and about 150 microns. As a specific, nonlimiting example, the maximum thickness of the second lead frame 110 may be between about 25 microns and about 100 microns (e.g., about 50 microns).

In some embodiments where each of the first lead frame 102 and the second lead frame 110 are at least substantially planar, each of the first lead frame 102 and the second lead frame 110 may be configured as a frame for a quad-flat no-leads package. For example, each of the first lead frame 102 and the second lead frame 110 may be fabricated from a sheet of metal material (e.g., the same sheet or respective, different sheets), and may present first output lands 126 and second output lands 132 at respective upper and lower peripheries of the resulting semiconductor device package 100 when the semiconductor device package 100 is in the orientation shown in FIG. 1. Such a configuration is shown in FIG. 1. A quad-flat no-leads package may optionally include a thermal management structure (e.g., a heat sink, a heat spreader) located centrally with respect to the first output lands 126 and/or second output lands 132. Such a thermal management structure may be in contact with a corresponding major surface of the semiconductor die 104, such as, for example, the first major surface 106, the second major surface 112, or a respective thermal management structure in contact with the first major surface 106 and another respective thermal management structure in contact with the second major surface 112.

In some embodiments, the second lead frame 110 may be electrically connected to the first lead frame 102 by one or more bridging elements 114. As one example, a single bridging element 114 may extend between the first lead frame 102 and the second lead frame 110, the bridging element 114 having at least substantially the same thickness as the semiconductor die 104 (e.g., the same thickness as the semiconductor die 104 plus the thickness of two conductive elements 108). Such a bridging element 114 may be in the form of, for example, a ball, bump, pillar, column, wire loop, or stud bump of wire of electrically conductive material (e.g., solder, gold, copper, aluminum, alloys). As another example, a first bridging element 116 may extend partially from the first lead frame 102 toward the second lead frame 110, a second bridging element 118 may extend partially from the second lead frame 110 toward the first bridging element 116, and any remaining space between the first lead frame 102, first bridging element 116, second bridging element 118, and second lead frame 110 may be occupied by a flowable, electrically conductive material (e.g., solder, conductive paste). The first bridging element 116 and the second bridging element 118 may include, for example, masses (e.g., slugs, wire loops, stud bumps of wire) of or including electrically conductive material (e.g., copper, gold, aluminum, alloys), or passive devices directly affixed, and electrically connected, to portions of the respective first lead frame 102 and/or second lead frame 110 laterally outside the footprint of the semiconductor die 104. In some embodiments, the second lead frame 110 may be electrically connected to the first lead frame 102 by direct contact between portions of the second lead frame 110 and the first lead frame 102 themselves, such as when the semiconductor die 104 has been ground sufficiently thin (e.g., less than half the thickness of one of the second lead frame 110 or first lead frame 102).

A molding material 120 may encapsulate each semiconductor die 104, each passive device, each bridging element 114, each first bridging element 116, each second bridging element 118, each conductive element 108, and at least portions of each of the first lead frame 102 and the second lead frame 110. For example, the molding material 120 may occupy a majority or more of a space that would otherwise be occupied by environmental gases between the first lead frame 102 and the second lead frame 110, up to those surfaces of the first lead frame 102 and the second lead frame 110 distal from the semiconductor die 104 (e.g., flush with, or recessed relative to, the first output lands 126 and the second output lands 132). More specifically, certain surfaces of the first lead frame 102 distal from the semiconductor die 104 may be exposed through the molding material 120 for electrical connection to higher-level packaging (e.g., in the form of first output lands 126, traces, lead fingers). In some embodiments, certain surfaces of the second lead frame 110 distal from the semiconductor die 104 may be exposed through the molding material 120 for electrical connection to higher-level packaging (e.g., in the form of second output lands 132, traces, lead fingers) and/or for thermal connection to a heat management structure (e.g., in the form of a thermal pad). In other embodiments, an entirety of the second lead frame 110 may be encapsulated within the molding material 120. The molding material 120 may be, for example, a selectively curable dielectric material (e.g., dielectric polymer, dielectric epoxy).

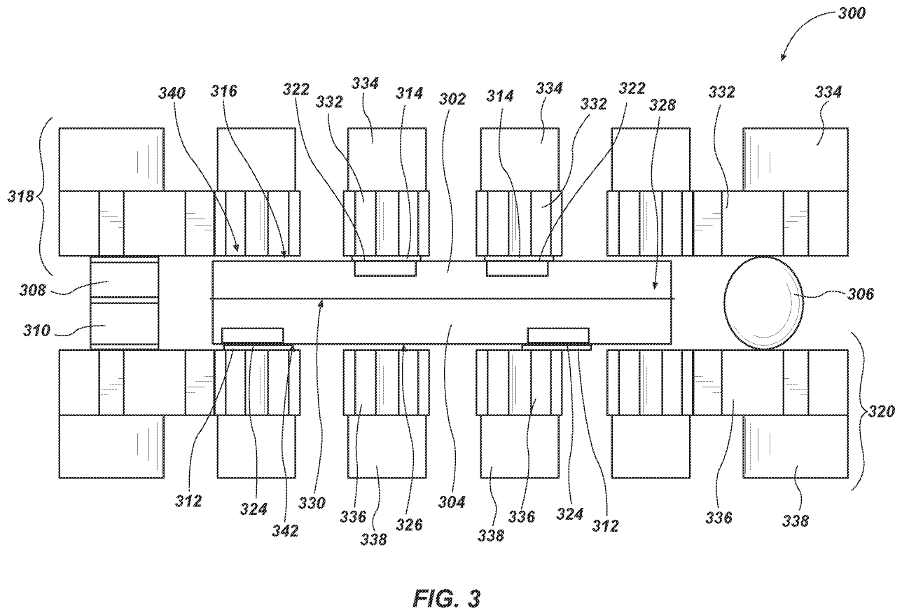

FIG. 3 is a cross-sectional, side, schematic view of another embodiment of a semiconductor device package 300 in accordance with this disclosure. As with FIG. 2 the molding material 120 (see FIG. 1) of the semiconductor device package 300 has been removed to more clearly illustrate the structure of the first lead frame 318 and the second lead frame 320 of the semiconductor device package 300.

In some embodiments, the semiconductor device package 300 may include multiple semiconductor dice within the same semiconductor device package 300, such as a first semiconductor die 302 and a second semiconductor die 304. For example, the first semiconductor die 302 may include a first major surface 316 configured as a first active surface having integrated circuitry embedded thereon and/or therein, and the second semiconductor die 304 may likewise include a second major surface 326 configured as a second active surface having integrated circuitry embedded thereon and/or therein. The first semiconductor die 302 may also include a third major surface 328 configured as a first inactive surface lacking any integrated circuitry, and the second semiconductor die 304 may include a fourth major surface 330 configured as a second inactive surface lacking any integrated circuitry.

In some embodiments, the first semiconductor die 302 and the second semiconductor die 304 may be placed in a back-to-back orientation, such that the first major surface 316 may be located on a side of the first semiconductor die 302 opposite, i.e. distal of, a side on which the second semiconductor die 304 is located, the second major surface 326 may be located on a side of the second semiconductor die 304 opposite, i.e. distal of, a side on which the first semiconductor die 302 is located (i.e., the first major surface 316 and the second major surface 326 may face away from one another). In such a back-to-back configuration, the third major surface 328 and the fourth major surface 330 may be located proximate to, and may face, one another (e.g., the third major surface 328 and the fourth major surface 330 may directly face one another with a curable polymer material, such as a dielectric underfill or the molding material 120 (see FIG. 1), therebetween).

In other embodiments, the first major surface 316 of the first semiconductor die 302 and the second major surface 326 of the second semiconductor die 304 may face in the same direction. In such a configuration, the first major surface 316 of the first semiconductor die 302 may be located proximate to, and may face, the fourth major surface 330 of the second semiconductor die 304 (e.g., the first major surface 316 and the fourth major surface 330 may directly face one another with a curable polymer material, such as a dielectric underfill or the molding material 120 (see FIG. 1), therebetween). As another example, the second major surface 326 of the second semiconductor die 304 may be located proximate to, and may face, the third major surface 328 of the first semiconductor die 302 (e.g., the second major surface 112 and the third major surface 328 may directly face one another with a curable polymer material, such as a dielectric underfill or the molding material 120 (see FIG. 1), therebetween).

First lead frame 318 may be positioned proximate to the first major surface 316 of the first semiconductor die 302 in some embodiments, with the first semiconductor die 302 placed in a first die-attach location 340 on the first lead frame 318. For example, the first major surface 316 may be affixed, and electrically connected, to the first lead frame 318. More specifically, the first semiconductor die 302 may be in a flip-chip orientation relative to the first lead frame 318, and first bond pads 322 of the first semiconductor die 302 exposed at the first major surface 316 may be electrically connected to the first lead frame 318 by first electrically conductive elements 314 interposed between the first bond pads 322 and the first lead frame 318. The first conductive elements 314 may be configured as, for example, balls, bumps, columns, pillars, or other shapes of, or including, electrically conductive material (e.g., solder, electrically conductive paste). The first conductive elements 314 may affix, and electrically connect, the first semiconductor die 302 to a die-attach pad, individual first lead fingers 332, or one or more first bond pads 322 to the die-attach pad and other first bond pads 322 to respective first lead fingers 332 for routing signals from integrated circuitry of the active surface to first output lands 334 of the first lead frame 318 and to higher-level packaging. As another example, the third major surface 328 of the first semiconductor die 302 may be affixed, and electrically connected, to the first lead frame 318, and the first major surface 316 may be located on a side of the first semiconductor die 302 opposite, i.e. distal of, a side on which the first lead frame 318 is located.

The first lead frame 318 may include, for example, electrically conductive material (e.g., copper, gold, aluminum, alloys) positioned and configured to carry and route electrical signals and/or power to and from the first semiconductor die 302. The first lead frame 318 may be at least substantially planar. For example, the first lead frame 318 may lack bends or lead fingers extending at oblique angles relative to the first major surface 316. More specifically, the first lead frame 318 may primarily be composed of one or more layers or sheets of electrically conductive material including first lead fingers 332 positioned and configured to form electrical connections with first bond pads 322 on the first major surface 316 of the first semiconductor die 302 (or with the third major surface 328 or bond pads thereon) and to route electrical signals and/or power to and from the first semiconductor die 302, and first output lands 334 positioned and configured to present locations for connection to higher-level packaging (e.g., a PCB). As a specific, nonlimiting example, the first lead frame 318 may be formed from a dual-depth etched sheet of electrically conductive material, and may include first lead finger 332 extending laterally proximate to the first major surface 316 of the first semiconductor die 302, some of which may be affixed, and electrically connected, to first bond pads 322 at the first major surface 316 (or with the third major surface 328 or bond pads thereon), and first output lands 334 located laterally outward from the first bond pads 322 and on a side of the first lead fingers 332 opposite, i.e. distal of, a side on which the first major surface 316 of the first semiconductor die 302 is located. In some embodiments, the first lead frame 318 may lack any die-attach pad.

A maximum thickness of the first lead frame 318, as measured in the direction at least substantially perpendicular to the first major surface 316, may be less than the thickness of a conventional lead frame having lead fingers extending at oblique angles relative to the first major surface 316. For example, the maximum thickness of the first lead frame 318 may be about 250 microns or less. More specifically, the maximum thickness of the first lead frame 318 may be between about 10 microns and about 150 microns. As a specific, nonlimiting example, the maximum thickness of the first lead frame 318 may be between about 25 microns and about 100 microns (e.g., about 50 microns).

The semiconductor device package 300 may further include second lead frame 320 positioned proximate to second major surface 326 of the second semiconductor die 304, with the second semiconductor die 304 placed in a second die-attach location 342 on the second lead frame 320. The second lead frame 320 may be on a side of the semiconductor device package 300 opposite the first lead frame 318. The second major surface 326 may be configured as, for example, an active surface including integrated circuitry supported thereon and/or embedded therein. In some embodiments, the second major surface 326 of the second semiconductor die 304 may be affixed, and electrically connected, to the second lead frame 320. For example, the second major surface 326 may be electrically connected to the second lead frame 320 by second electrically conductive elements 312 interposed between the second lead frame 320 and a die-attach pad of the second lead frame 320, which may form, for example, a ground plane and/or an exposed surface for thermally connecting to a thermal management device. As another example, second bond pads 324 may be exposed at the second major surface 326 of the second semiconductor die 304, and the second bond pad 324 may be operatively and electrically connected to integrated circuitry at the second major surface 326, and at least one of the second lead fingers 336 may be attached, and electrically connected, to a corresponding one of the second bond pads 324. As another example, the fourth major surface 330 of the second semiconductor die 304 may be affixed, and electrically connected, to the second lead frame 320, and the second major surface 326 may be located on a side of the second semiconductor die 304 opposite, i.e. distal of, a side on which the second lead frame 320 is located.

The second lead frame 320 may include, for example, electrically conductive material (e.g., copper, gold, aluminum, alloys) positioned and configured to carry and route electrical signals and/or power to and from the second semiconductor die 304 and/or to provide electrical ground for the second semiconductor die 304. The second lead frame 320 may be at least substantially planar. For example, the second lead frame 320 may lack bends or lead fingers extending at oblique angles relative to the second major surface 326. More specifically, the second lead frame 320 may primarily be composed of one or more layers or sheets of electrically conductive material including second lead fingers 336 positioned and configured to form electrical connections with the second major surface 326 itself and/or with second bond pads 324 on the second major surface 326 of the second semiconductor die 304 and to route electrical signals and/or power to and from the second semiconductor die 304, and second output lands 338 positioned and configured to present locations for connection to higher-level packaging (e.g., a PCB). As a specific, nonlimiting example, the second lead frame 320 may be formed from a dual-depth etched sheet of electrically conductive material, and may include second lead fingers 336 extending laterally proximate to the second major surface 326 of the second semiconductor die 304, some of which second lead fingers 336 may be affixed, and electrically connected, to second bond pads 324 at the second major surface 326, and second output lands 338 located laterally outward from any second bond pads 324 and on a side of the second lead fingers 336 opposite, i.e. distal of, a side on which the second major surface 326 of the second semiconductor die 304 is located. In some embodiments, the second lead frame 320 may lack any die-attach pad.

A maximum thickness of the second lead frame 320, as measured in the direction at least substantially perpendicular to the second major surface 326, may be less than the thickness of a conventional lead frame having lead fingers extending at oblique angles relative to the second major surface 326. For example, the maximum thickness of the second lead frame 320 may be about 250 microns or less. More specifically, the maximum thickness of the second lead frame 320 may be between about 10 microns and about 150 microns. As a specific, nonlimiting example, the maximum thickness of the second lead frame 320 may be between about 25 microns and about 100 microns (e.g., about 50 microns).

In some embodiments, the second lead frame 320 may be electrically connected to the first lead frame 318 by one or more bridging elements 306. As one example, a single bridging element 306 may extend between the first lead frame 318 and the second lead frame 320, the bridging element 306 having at least substantially the same thickness as the combined thicknesses of the first semiconductor die 302 and the second semiconductor die 304 (e.g., the same thickness as the first semiconductor die 302, plus the thickness of the second semiconductor die 304, plus the thickness of one first conductive element 314 plus one second conductive element 312). Such a bridging element 306 may be in the form of, for example, a ball, bump, pillar, or column of, or including, electrically conductive material (e.g., solder). As another example, a first passive electronic device 308 may extend partially from the first lead frame 318 toward the second lead frame 320, a second passive electronic device 310 may extend partially from the second lead frame 320 toward the first passive electronic device 308, and any remaining space between the first lead frame 318, first passive electronic device 308, second passive electronic device 310, and second lead frame 320 may be occupied by a flowable, electrically conductive material (e.g., solder, conductive paste). The first passive electronic device 308 and the second passive electronic device 310 may include, for example, capacitors, resistors, or combinations of these directly affixed, and electrically connected, to portions of the respective first lead frame 318 and/or second lead frame 320 laterally outside the footprints of the first semiconductor die 302 and the second semiconductor die 304.

In some embodiments, the first semiconductor die 302 and the second semiconductor die 304 may be electrically and operatively interconnected to one another. For example, the bridging elements 306 may serve to route electrical signals and/or power between the first semiconductor die 302 and the second semiconductor die 304 via the first lead frame 318 and the second lead frame 320. As another example, additional electrically conductive elements (e.g., solder bumps, balls, pillars, columns) may be interposed between those surfaces of the first semiconductor die 302 and the second semiconductor die 304 located proximate to, and directly facing, one another, such as, for example, the third major surface 328 and the fourth major surface 330. Such additional electrically conductive elements may be affixed, and electrically connected, to additional bond pads exposed at the third major surface 328 and the second major surface 326, which may be electrically connected to integrated circuitry at the first major surface 316 and the second major surface 326, respectively, by TSVs.

A molding material 120 (see FIG. 1) may encapsulate the first semiconductor die 302, the second semiconductor die 304, the first passive electronic devices 308, the second passive electronic devices 310, each bridging element 306, the first conductive elements 314, the second conductive elements 312, and at least portions of each of the first lead frame 318 and the second lead frame 320. For example, the molding material 120 (see FIG. 1) may be configured at least substantially as described previously in connection with FIG. 1.

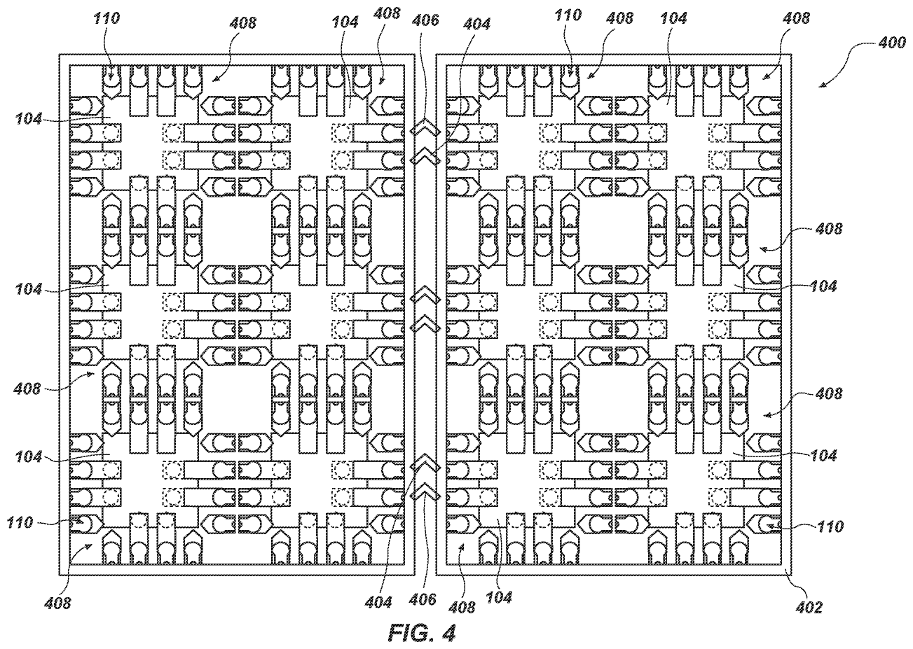

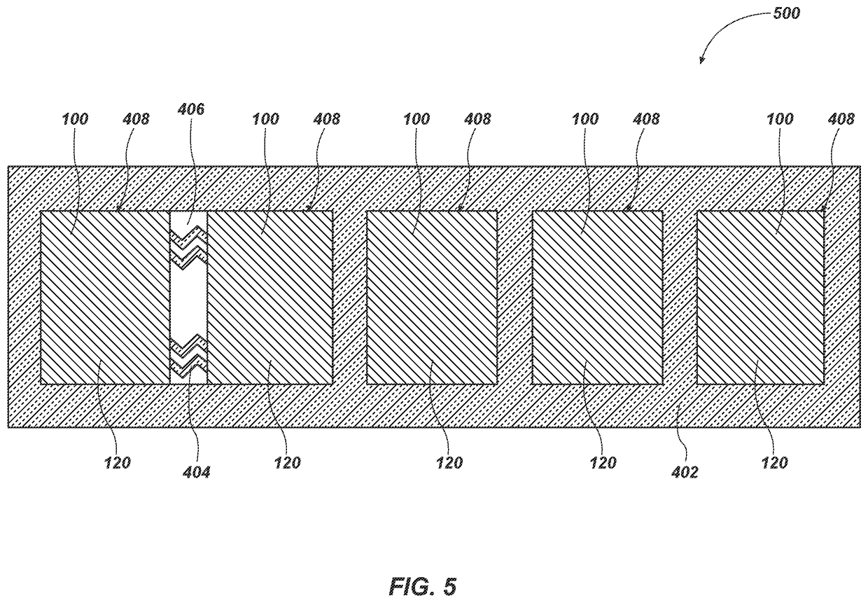

FIG. 4 is a top schematic view of a first intermediate product 400 in a first stage of a method of concurrently making multiple semiconductor device packages. FIG. 5 is a top schematic view of a second intermediate product 500 in a method of concurrently making multiple semiconductor device packages. Specifically FIG. 4 illustrates a first intermediate product 400 in a pre-encapsulation stage, and FIG. 5 illustrates a second intermediate product 500 in a subsequent, post-encapsulation stage, of the method of concurrently making multiple semiconductor device packages.

With combined reference to FIG. 4 and FIG. 5, the first lead frame 102 (see FIG. 1) and the second lead frame 110 may be provided as, for example, groups of first lead frames 102 (see FIG. 1) and second lead frames 110 in strips 402 having multiple instances of the first lead frame 102 (see FIG. 1) and the second lead frame 110 distributed over the area of the strip 402. Those strips 402 may be made from, or include, the materials used to form the first lead frames 102 (see FIG. 1) and the second lead frames 110. For example, subtractive manufacturing techniques (e.g., laser cutting, water jetting, etching, milling, etc.) may be used to form the strips 402 and associated first lead frames 102 (see FIG. 1) and second lead frames 110 from a sheet or plate of or including electrically conductive material (e.g., copper, aluminum, gold, alloys or combinations thereof, etc.). Semiconductor dice 104 may be placed in respective semiconductor device package locations 408 on the strips 402, and appropriate mechanical and electrical connections between the semiconductor dice 104 and the associated first lead frames 102 and second lead frame 110 may be made. Any mechanical and electrical connections between portions of the first lead frames 102 and the second lead frames 110 themselves, as well as mechanical and electrical connections between any passive devices and the first lead frames 102 and/or second lead frames 110, may be made.

A mold may be placed over the semiconductor device package locations 408, and the molding material 120 may be introduced into the mold while in a flowable state. The molding material 120 may flow to fill those spaces within the mold not already occupied by the first lead frames 102, second lead frames 110, strips 402, semiconductor dice 104, bridging elements 114 (see FIG. 1), and any passive devices. The molding material 120 may then be solidified (e.g., by curing) to encapsulate the components of the semiconductor device packages 100, and the semiconductor device packages 100 may be singulated from one another and from any remainders of the strips 402 to form the semiconductor device packages 100.

In some embodiments, one or more of the strips 402 may include one or more strain-relief features 406 to reduce the likelihood that clamping from the mold will damage any of the components of the semiconductor device packages 100. One or more of the strips 402 may include gaps, voids, or otherwise material-free regions between semiconductor device package locations 408 of the strips 402. Connective materials 404 may extend across the gaps, the connective materials 404 being positioned and configured to support the strips 402 across the gaps, and to deform in response to introduction of the mold to reduce the likelihood that the mold's clamping force will damage components of the semiconductor device packages 100. For example, the connective material 404 may include accordion strips, springs, or other deformable structures of the material of the strips 402 extending across the gap of the strain-relief features 406. The connective materials 404 of the strain-relief features 406 may be formed by, for example, removing at least certain portions of the material of the strips 402 located proximate to the connective material 404.

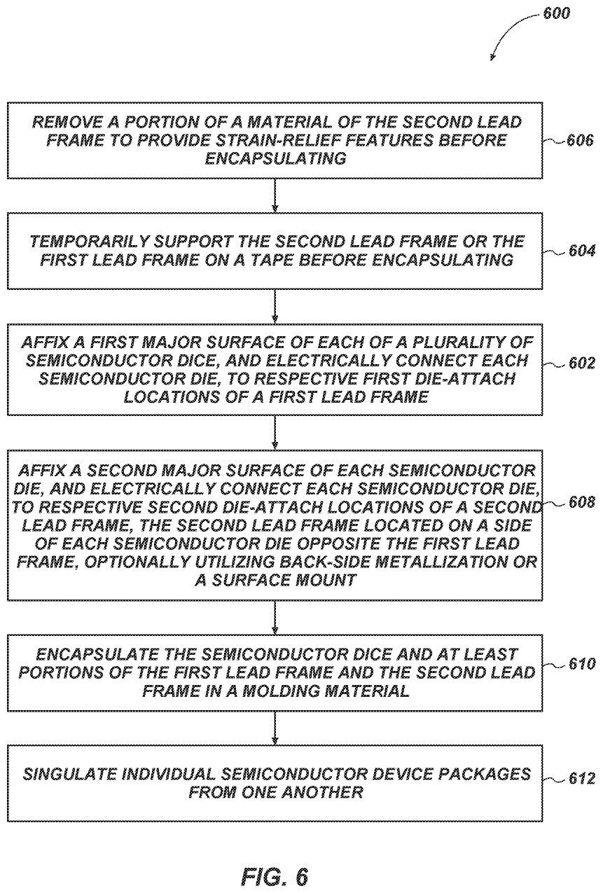

FIG. 6 is a flowchart of a method 600 of concurrently making multiple semiconductor device packages 100 (see FIG. 1). The method 600 may involve, for example, affixing a first major surface 106 (see FIG. 1) of each of a plurality of semiconductor dice 104 (see FIG. 1), and electrically connecting each semiconductor die 104 (see FIG. 1), to respective first die-attach locations 134 (see FIG. 1) of a first lead frame 102 (see FIG. 1), as indicated at act 602. More specifically, first bond pads 122 (see FIG. 1) of the first major surface 106 (see FIG. 1) of each of the plurality of semiconductor dice 104 (see FIG. 1) may be, for example, brought proximate to corresponding first lead fingers 124 (see FIG. 1) of a respective first lead frame 102 (see FIG. 1) at a given first die-attach location 134 (see FIG. 1) on the strip 402 (see FIG. 4), with a conductive element 108 (see FIG. 1) between each first bond pad 122 (see FIG. 1) and each associated first lead finger 124 (see FIG. 1). The conductive elements 108 (see FIG. 1) may be reflowed (e.g., through exposure to heat) to electrically and mechanically connect each semiconductor die 104 (see FIG. 1) to the associated first die-attach location 134 (see FIG. 1) of a respective first lead frame 102 (see FIG. 1) in the strip 402 (see FIG. 4).

A second major surface 112 (see FIG. 1) of each semiconductor die 104 (see FIG. 1) may be affixed, and each semiconductor die 104 (see FIG. 1) may be electrically connected, to respective second die-attach locations 136 (see FIG. 1) of a second lead frame 110 (see FIG. 1), with the second lead frame 110 (see FIG. 1) located on a side of each semiconductor die 104 (see FIG. 1) opposite the first lead frame 102 (see FIG. 1), as indicated at act 608. For example, a second major surface 112 (see FIG. 1) or second bond pads 128 (see FIG. 1) of the second major surface 112 (see FIG. 1) of each of the plurality of semiconductor dice 104 (see FIG. 1) may be brought proximate to corresponding second lead fingers 130 (see FIG. 1) of a respective second lead frame 110 (see FIG. 1) at a given second die-attach location 136 (see FIG. 1) on the strip 402 (see FIG. 4), with a conductive element 108 (see FIG. 1) between each second bond pad 128 (see FIG. 1) and each associated second lead finger 130 (see FIG. 1). The conductive elements 108 (see FIG. 1) may be reflowed (e.g., through exposure to heat) to electrically and mechanically connect each semiconductor die 104 (see FIG. 1) to the associated second die-attach location 136 (see FIG. 1) of a respective second lead frame 110 (see FIG. 1) in the strip 402 (see FIG. 4). Optionally, the second major surface 112 may be electrically connected to the second lead frame 110 by a back-side metallization process (e.g., sputtering) or a surface mount (e.g., directly contacting the second lead frame 110 to the second major surface 112 with an electrically conductive material, such as, for example, solder, conductive paste, etc., therebetween), as also indicated at act 608.

The semiconductor dice 104 (see FIG. 1) and at least portions of the first lead frame 102 (see FIG. 1) and the second lead frame 110 (see FIG. 1) may be encapsulated in a molding material 120 (see FIG. 1), as indicated at act 610. For example, a mold may be brought into contact with the strip 402 (see FIG. 4), and a quantity of the molding material 120 (see FIG. 1) in a flowable state may be introduced into the mold to at least substantially occupy any free space between and around the semiconductor dice 104 (see FIG. 1), first lead frame 102 (see FIG. 1), and second lead frame 110 (see FIG. 1). The mold molding material 120 (see FIG. 1) may then be cured (e.g., in response to application of heat, exposure to radiation of a specific type and/or frequency) to encapsulate the semiconductor dice 104 (see FIG. 1), portions of the first lead frame 102 (see FIG. 1), and second lead frame 110 (see FIG. 1), leaving at least portions of the first output lands 126 (see FIG. 1) and second output lands 132 (see FIG. 1) exposed for connection to higher-level packaging.

Following encapsulation, individual semiconductor device packages 100 may be singulated from one another in some embodiments, as indicated at act 612. For example, a saw may be used to cut through those portions of the first lead frame 102 (see FIG. 1) and the second lead frame 110 (see FIG. 1) that previously attached them to a remainder of the strip 402 (see FIG. 4) (e.g., to a frame or border region at a periphery of the strip 402 (see FIG. 4).

Prior to encapsulation, the second lead frame 110 (see FIG. 1) or the first lead frame 102 (see FIG. 1) may be temporarily supported on a tape 138 (see FIG. 1) in some embodiments, as indicated at act 604. For example, outermost portions of the first lead frame 102 (see FIG. 1) or the second lead frame 110 (see FIG. 1) may be temporarily adhered to an adhesive, flexible tape 138 (see FIG. 1) to provide support for the strip 402 (see FIG. 1) during transport and processing (e.g., encapsulation).

Before encapsulation, a portion of a material of the second lead frame 110 (see FIG. 1) or the first lead frame 102 (see FIG. 1) may be removed to provide strain-relief features 406 before encapsulating. For example, portions of the second lead frame 110 (see FIG. 1) or the first lead frame 102 (see FIG. 1) that may be removed when singulating the semiconductor device packages 100 (see FIG. 1) from one another, such as those located between adjacent semiconductor device package locations 408 (see FIG. 1), may be removed to leave connective material 404 (see FIG. 4) between the semiconductor device package location 408 (see FIG. 4), as indicated at act 606.

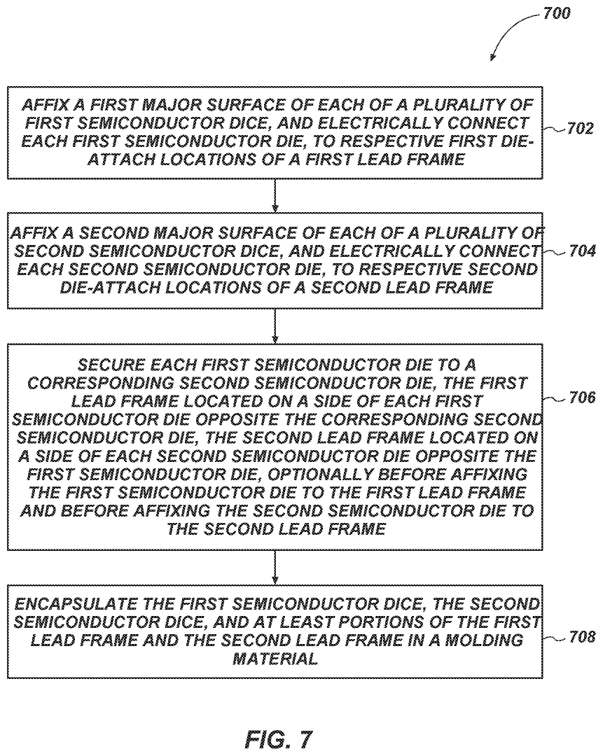

FIG. 7 is a flowchart of another embodiment of a method 700 of concurrently making multiple semiconductor device packages 300 (see FIG. 3). The method 700 may involve, for example, affixing a first major surface 316 (see FIG. 3) of each of a plurality of first semiconductor dice 302 (see FIG. 3), and electrically connecting each first semiconductor die 302 (see FIG. 30, to respective first die-attach locations 340 (see FIG. 3) of a first lead frame 318 (see FIG. 3), as shown at act 702. More specifically, first bond pads 322 (see FIG. 3) of the first major surface 316 (see FIG. 3) of each of the plurality of first semiconductor dice 302 (see FIG. 3) may be, for example, brought proximate to corresponding first lead fingers 332 (see FIG. 3) of a respective first lead frame 318 (see FIG. 3) at a given first die-attach location 340 (see FIG. 3) on the strip 402 (see FIG. 4), with a first conductive element 314 (see FIG. 3) between each first bond pad 322 (see FIG. 3) and each associated first lead finger 332 (see FIG. 3). The first conductive elements 314 (see FIG. 3) may be reflowed (e.g., through exposure to heat) to electrically and mechanically connect each first semiconductor die 302 (see FIG. 3) to the associated first die-attach location 340 (see FIG. 3) of a respective first lead frame 318 (see FIG. 3) in the strip 402 (see FIG. 4).

A second major surface 326 (see FIG. 3) of each of a plurality of second semiconductor dice 304 (see FIG. 3) may be affixed, and each second semiconductor die 304 (see FIG. 3) may be electrically connected, to respective second die-attach locations 342 (see FIG. 3) of a second lead frame 320 (see FIG. 3), as indicated at act 704. For example, second bond pads 324 (see FIG. 3) of the second major surface 326 (see FIG. 3) of each of the plurality of second semiconductor dice 304 (see FIG. 3) may be brought proximate to corresponding second lead fingers 336 (see FIG. 3) of a respective second lead frame 320 (see FIG. 3) at a given second die-attach location 342 (see FIG. 3) on the strip 402 (see FIG. 4), with a second conductive element 312 (see FIG. 3) between each second bond pad 324 (see FIG. 3) and each associated second lead finger 336 (see FIG. 3). The second conductive elements 312 (see FIG. 3) may be reflowed (e.g., through exposure to heat) to electrically and mechanically connect each second semiconductor die 304 (see FIG. 3) to the associated second die-attach location 342 (see FIG. 3) of a respective second lead frame 320 (see FIG. 3) in the strip 402 (see FIG. 4).

Each first semiconductor die 302 (see FIG. 3) may be secured to a corresponding second semiconductor die 304 (see FIG. 3), with the first lead frame 318 (see FIG. 3) located on a side of each first semiconductor die 302 (see FIG. 3) opposite, i.e. distal of, a side on which the corresponding second semiconductor die 304 (see FIG. 3) is located, and the second lead frame 320 (see FIG. 3) located on a side of each second semiconductor die 304 (see FIG. 3) opposite, i.e. distal of, a side on which the first semiconductor die 302 (see FIG. 3) is located, as indicated at act 706. For example, inactive third major surfaces 328 (see FIG. 3) may be oriented to face, and may remain spaced from, inactive fourth major surfaces 330 (see FIG. 3), to enable a flowable molding material 120 (see FIG. 1) to flow between each first semiconductor die 302 (see FIG. 3) and each corresponding second semiconductor die 304 (see FIG. 3) and be cured to secure them to one another. In some embodiments, each first semiconductor die 302 (see FIG. 3) may be secured to the corresponding second semiconductor die 304 (see FIG. 3) before affixing the first major surface 316 (see FIG. 3) of each of the plurality of first semiconductor dice 302 (see FIG. 3) to the respective first die-attach locations 340 (see FIG. 3) of the first lead frame 318 (see FIG. 3) and before affixing the second major surface 326 (see FIG. 3) of each of the plurality of second semiconductor dice 304 (see FIG. 3) to the respective second die-attach locations 342 (see FIG. 3) of the second lead frame 320 (see FIG. 3). For example, an adhesive material (e.g., a curable polymer material) directly interposed between, and in contact with each of, the third major surface 328 (see FIG. 3) and the fourth major surface 330 (see FIG. 3) may attach the first semiconductor die 302 (see FIG. 3) to the second semiconductor die 304 (see FIG. 3).

In some embodiments, securing each first semiconductor die 302 (see FIG. 3) to the corresponding second semiconductor die 304 (see FIG. 3) comprises securing each first semiconductor die 302 (see FIG. 3) to the corresponding second semiconductor die 304 (see FIG. 3) before affixing the first major surface 316 (see FIG. 3) of each of the plurality of first semiconductor dice 302 (see FIG. 3) to the respective first die-attach locations 340 (see FIG. 3) of the first lead frame 318 (see FIG. 3) and before affixing the second major surface 326 (see FIG. 3) of each of the plurality of second semiconductor dice 302 (see FIG. 3) to the respective second die-attach locations 342 (see FIG. 3) of the second lead frame (320 (see FIG. 3).

The first semiconductor dice 302 (see FIG. 3), the second semiconductor dice 304 (see FIG. 3), and at least portions of the first lead frame 318 (see FIG. 3) and the second lead frame 320 (see FIG. 3) may be encapsulated in a molding material 120 (see FIG. 1), as indicated at act 708. For example, a mold may be brought into contact with the strip 402 (see FIG. 4), and a quantity of the molding material 120 (see FIG. 1) in a flowable state may be introduced into the mold to at least substantially occupy any free space between and around the first semiconductor dice 302 (see FIG. 3), second semiconductor dice 304 (see FIG. 3), first lead frame 318 (see FIG. 3), and second lead frame 320 (see FIG. 3). The mold molding material 120 (see FIG. 1) may then be cured (e.g., in response to application of heat, exposure to radiation of a specific type and/or frequency) to encapsulate the first semiconductor dice 302 (see FIG. 3), the second semiconductor dice 304 (see FIG. 3), portions of the first lead frame 318 (see FIG. 3), and second lead frame 320 (see FIG. 3), leaving at least portions of the first output lands 334 (see FIG. 3) and second output lands 338 (see FIG. 3) exposed for connection to higher-level packaging.

Embodiments of semiconductor device packages and methods of fabricating semiconductor device packages in accordance with this disclosure may utilize multiple lead frames having one or more semiconductor devices interposed between the lead frames. Such configurations may enable electrical connection on opposite sides of the semiconductor device packages, which may enable stacked, interconnected package configurations (e.g., package-on-package (PoP) configurations). In addition, semiconductor device packages in accordance with this disclosure may enable deployment of multiple semiconductor dice within a given semiconductor device package, facilitating manufacture of semiconductor device packages having enhanced and more flexible functionality (e.g., systems-on-a-chip). Furthermore, techniques for fabricating semiconductor device packages in accordance with this disclosure may enable collective, concurrent packaging of multiple semiconductor device packages, may provide exposed structures for electrical and thermal management connections, and may be implementable with little added cost to existing packaging processes.

While certain illustrative embodiments have been described in connection with the figures, those of ordinary skill in the art will recognize and appreciate that the scope of this disclosure is not limited to those embodiments explicitly shown and described in this disclosure. Rather, many additions, deletions, and modifications to the embodiments described in this disclosure may be made to produce embodiments within the scope of this disclosure, such as those specifically claimed, including legal equivalents. In addition, features from one disclosed embodiment may be combined with features of another disclosed embodiment while still being within the scope of this disclosure.

What is claimed is:

1. A semiconductor device package, comprising:
a semiconductor die comprising a first major surface affixed and electrically connected to a first lead frame;
a second lead frame affixed and electrically connected to a second major surface of the semiconductor die, the second major surface located on a side of the semiconductor die opposite the first major surface; and
a molding material encapsulating the semiconductor die and at least portions of the first lead frame and the second lead frame.

2. The semiconductor device package of claim 1, wherein the first lead frame is electrically connected to the second lead frame.

3. The semiconductor device package of claim 2, further comprising a solder material extending between the first lead frame and the second lead frame thereby electrically connecting the first lead frame to the second lead frame.

4. The semiconductor device package of claim 2, further comprising at least one discrete mass of electrically conductive material or at least one passive electronic device forming at least a portion of an electrical connection between the first lead frame and the second lead frame thereby electrically connecting the first lead frame to the second lead frame.

5. The semiconductor device package of claim 1, wherein the first major surface is electrically connected to the first lead frame by a flip-chip connection.

6. The semiconductor device package of claim 1, wherein the second major surface is electrically connected to the second lead frame by a back-side metallization process or a surface mount.

7. The semiconductor device package of claim 1, wherein each of the first lead frame and the second lead frame is at least substantially planar.

8. The semiconductor device package of claim 1, wherein each of the first lead frame and the second lead frame is configured as a frame for a quad-flat no-leads package.

9. The semiconductor device package of claim 1, wherein portions of the first lead frame are exposed through the molding material for electrically connecting to higher level packaging.

10. The semiconductor device package of claim 1, wherein portions of the second lead frame are exposed through the molding material for electrically connecting to higher level packaging or to a heat management structure.

11. The semiconductor device package of claim 1, wherein the second lead frame is encapsulated within the molding material.

12. A semiconductor device package, comprising:
a first semiconductor die comprising a first major surface affixed and electrically connected to a first lead frame;
a second semiconductor die comprising a second major surface affixed and electrically connected to a second lead frame, the second semiconductor die comprising a third major surface affixed to a fourth major surface of the first semiconductor die, such that the first lead frame is located on a side of the first semiconductor die distal the second semiconductor die and the second lead frame is located on a side of the second semiconductor die distal the first semiconductor die; and
a molding material encapsulating the first semiconductor die, the second semiconductor die, and at least portions of the first lead frame and the second lead frame.

13. The semiconductor device package of claim 12, wherein each of the first lead frame and the second lead frame is configured as a frame for a quad-flat no-leads package.

14. The semiconductor device package of claim 12, further comprising at least one bridging element electrically connecting the first lead frame to the second lead frame.

15. A method of concurrently making semiconductor device packages, comprising:
affixing a first major surface of each of a plurality of semiconductor dice, and electrically connecting each semiconductor die, to respective first die-attach locations of a first lead frame;
affixing a second major surface of each semiconductor die, and electrically connecting each semiconductor die, to respective second die-attach locations of a second lead frame, the second lead frame located on a side of each semiconductor die opposite the first lead frame; and
encapsulating the semiconductor dice and at least portions of the first lead frame and the second lead frame in a molding material.

16. The method of claim 15, further comprising singulating individual semiconductor device packages from one another.

17. The method of claim 15, further comprising temporarily supporting the second lead frame or the first lead frame on a tape before encapsulating.

18. The method of claim 15, further comprising removing a portion of a material of the second lead frame to provide strain-relief features before encapsulating.

19. A method of concurrently making semiconductor device packages, comprising:
affixing a first major surface of each of a plurality of first semiconductor dice, and electrically connecting each first semiconductor die, to respective first die-attach locations of a first lead frame;
affixing a second major surface of each of a plurality of second semiconductor dice, and electrically connecting each second semiconductor die, to respective second die-attach locations of a second lead frame;
securing each first semiconductor die to a corresponding second semiconductor die, the first lead frame located on a side of each first semiconductor die distal of the corresponding second semiconductor die, the second lead frame located on a side of each second semiconductor die distal of the first semiconductor die; and
encapsulating the first semiconductor dice, the second semiconductor dice, and at least portions of the first lead frame and the second lead frame in a molding material.

20. The method of claim 19, wherein securing each first semiconductor die to the corresponding second semiconductor die comprises securing each first semiconductor die to the corresponding second semiconductor die before affixing the first major surface of each of the plurality of first semiconductor dice to the respective first die-attach locations of the first lead frame and before affixing the second major surface of each of the plurality of second semiconductor dice to the respective second die-attach locations of the second lead frame.
